(19) United States
(12) Patent Application Publication
(10) Pub. No.: US 2015/0014044 A1
(43) Pub. Date: Jan. 15, 2015

(54) HIGH SPEED VIA

(71) Applicant: International Business Machines Corporation, Armonk, NY (US)

(72) Inventors: Eric R. Ao, Nepean (CA); Donald R. Dignam, Ottawa (CA); Stephen J. Flint, Ottawa (CA)

(21) Appl. No.: 13/941,644

(22) Filed: Jul. 15, 2013

(51) Int. Cl. H05K 3/00; H05K 1/11

(52) U.S. Cl. CPC H05K 3/0005; H05K 1/115
USPC 174/266; 716/137

(57) ABSTRACT

A method is used for designing a multilayered circuit substrate that generates a physical design layout. The physical design layout represents of at least one electrical circuit passing through a plurality of layers. Based on performance requirements of the electrical circuit, a maximum allowable stub length of a via in the electrical circuit is computed. The computer processor determines if a stub length of an existing via in the physical design layout of the electrical circuit is less than the maximum allowable stub length. If the computer determines that the stub length of the existing via is less than the maximum allowable stub length, the computer removes an external non-functional pad of the existing via from the physical design layout.

### FIELD OF THE INVENTION

The present invention relates generally to high speed digital circuit technology, and more particularly to printed circuit board technology used in high speed circuits.

### BACKGROUND OF THE INVENTION

In addition to increasing speeds in traditional computing, the advent of wireless digital communication technologies, such as cell phones, smart phones, wireless networking, and global positioning systems (GPS), drive increasing focus in circuit design and electronic components and systems. The design and manufacture of high speed circuit boards that handle signals within the gigahertz range is in demand in the electronics industry. These high frequency applications start with speeds in the gigahertz range (GHz) and quickly have moved far beyond these speeds. Circuit layout and design of high speed digital circuit boards typically use microstrips or striplines for transmission of digital circuitry with high frequencies.

High speed circuit boards traditionally utilize multilayer structures with signal transmission lines that are interconnected between layers by electrically conductive vias. While necessary in multilayer printed circuit boards (PCB) to connect signal lines and planes in different PCB layers, vias are typical discontinuities for high speed signal transmission. In conventional PCB manufacture, vias are drilled in a metal/dielectric composite where the dielectric material can be an epoxy impregnated glass cloth or similar material. The vias are then typically plated with copper for electrical continuity. There are several types of vias utilized in traditional PCB design. Plated through holes (PTH), buried vias, and blind vias are standard for PCB design. The effect of vias on PCB performance becomes increasingly important with the movement to increasing circuit speeds driven by wireless communications technology and other high speed applications.

### SUMMARY

The present invention provides a method for designing a multilayered circuit substrate where the non-functional via pads are removed from high speed circuits. The method includes generating a physical design layout where the physical design layout is a representation of at least one electrical circuit passing through a plurality of layers. Based on performance requirements of the electrical circuit, a maximum allowable stub length for vias in the electrical circuit is computed. Determining by one or more computer processors, whether a stub length of a via in the physical design layout of an electrical circuit is less than the maximum allowable stub length. When the stub length of the via is less than the maximum allowable stub length, the computer removes an external non-functional pad from the via in the physical design layout.

A multilayered circuit substrate has a plurality of electrical circuits passing through a plurality of layers of a multilayered circuit substrate, where each of the plurality of electrical circuits comprises at least one via electrically connecting one conductive layer and second conductive layer. Each via, of the plurality of electrical circuits, having a stub-length less than a defined maximum allowable stub-length, terminates at an external layer of the plurality of layers without a non-functioning conductive pad. Each via, of the plurality of electrical circuits, having a stub-length equal to or greater than the defined maximum allowable stub-length, terminates at an internal layer wherein a stub of the via has been removed.

### BRIEF DESCRIPTION OF THE SEVERAL VIEWS OF THE DRAWINGS

FIG. 1 is a flow chart illustrating exemplary steps of an embodiment of the present invention.

FIG. 2 depicts a cross-sectional view of a multilayered printed circuit board in accordance with an embodiment of the present invention.

FIG. 3 illustrates a cross-sectional view of a multilayered printed circuit board in accordance with an embodiment of the present invention.

FIG. 4 depicts a cross-sectional view of a multilayered printed circuit board in accordance with an embodiment of the present invention.

### DETAILED DESCRIPTION

Embodiments of the present invention provide a high speed via for printed circuit boards. One skilled in the art will recognize that concepts developed in exemplary embodiments of the present invention could be applied to other multilayered circuit substrates, for example laminate chip carrier design, ceramic chip carrier design and other multilayer circuit substrates including semiconductor design applications. Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In today's fast growing digital system design field, speeds are rapidly increasing, driving better technologies, designs, circuits and models to handle multi-gigahertz signal transmissions (100 G Ethernet for example). As these technologies drive higher and higher speeds, challenges are created at all levels of circuit design. High speed PCBs with increasing wiring density, increasing frequencies and switching speeds see similarly increasing problems with signal integrity.

Printed circuit board technology typically consists of a non-conducting dielectric layer, traditionally, an epoxy impregnated glass cloth or similar dielectric material on which a conductive layer like copper is laminated or deposited. Signal lines and power planes are etched or selectively plated on the layers. One or more layers of insulating and conductive materials with signal lines and/or power planes are laminated together. Vias are drilled and plated or filled with conductive material, such as silver filled epoxy or other conductive material, to make electrical connections between signals on different layers of the printed circuit board for various electrical components. Vias also may be etched, laser drilled or otherwise created in some more specialized PCB applications.

There are several types of vias commonly used in PCB technology today. Plated through-holes or PTH's are drilled completely through a fully laminated PCB. In other words, all layers of the PCB are drilled through from one side of the PCB to the other side (through both external layers). The drilled holes are typically electroplated with copper to create electrical connections between various PCB layers. Buried vias are typically drilled and plated or electrically filled within one or several internal layers of the PCB before final lamination. They are not drilled through the PCB and do not extend to either outer surface of the PCB (internal layer connections). Blind vias extend from one surface or external layer to one or more layers in the PCB but, do not extend through the PCB.

Traditionally, vias terminate on a circuitized via pad (usually, copper) that is etched or selectively electroplated on the surface of individual layers. Via pads are usually used in internal signal planes and on external PCB layers. Via diameter and via pad size are determined by the electrical design and manufacturing requirements that are determined by drill wander, via aspect ratio, electroplating requirements, manufacturing yields and similar process concerns. Often, PCB manufacturers provide PCB design guidelines for drilling, pad sizes, circuitization spacing, etc. to hardware designers as driven by manufacturing process yields.

Vias, used to connect signal lines and planes in different layers, are one of the more frequently used interconnect structures in high speed PCB technology. While they have little impact on lower frequency designs with slower rise times, they can have a significant impact on high speed designs. In high frequency applications, vias are a discontinuity that can lead to signal reflection, attenuation, and other signal integrity issues. For example, signal to via connections can cause high speed signals to be reflected, resulting in transmission loss and jitter. Strong crosstalk and noise coupling may occur in adjacent vias when a high speed signal flows in a signal via and excites the parallel plane waves inside a parallel plane pair. For differential signals, via structures may contribute to the mode conversion from differential mode to common mode conversion, resulting in electromagnetic interference issues. These are examples of a few of the challenges arising from vias in high frequency designs.

To reduce the effects of vias on a high speed circuit design several PCB design and manufacturing methods have been used. For these high speed signals, it is desirable to keep the electrical conductor cross-section uniform. A change in the signal trace cross-section of the conductor perpendicular to the direction of the signal flow will typically alter the complex impedance of the conductor causing reflection and signal dispersion. In most vias there is significant conductive material where copper is plated or solder from a component attach operation, like surface mount soldering, flows into vias or other conductive via fill material is applied. In addition, via pads both on internal layers and external layers add to the signal discontinuities.

One method utilized in high speed design to reduce the effect of signal line discontinuities due to vias is using a smaller via or PTH and smaller via pads to lessen size difference between the high speed signal line and via cross-section. Another method is removing unused or non-functional via pads from the internal PCB planes. A non-functional via pad is a via pad that does not connect to a signal line or electrical conductor. Conversely, a functional via pad is one that is connected to signal line or electrical conductor. It is common practice in PCB design to include via pads on all signal or power planes. While in some applications via pads are a requirement to improve mechanical reliability of the PCB, removing the non-functional via pads from the PCB internal layers is not detrimental to reliability in many cases.

Another method used to reduce the effect of the discontinuity caused by vias on a high speed signal in PCB is a manufacturing back-drill to remove unused via elements. This is done when only a small portion of a PTH is used for signal transmission. When a lengthy portion of the PTH is not used for active circuit connection, this unused portion of the PTH is selectively drilled out (back drilled). The unused portion of the via or PTH is called a “stub” since it is not a part of the active circuit path. A stub is undesirable in high speed circuit design since it causes a reflection which degrades signal integrity. The back-drill method is used to remove the unused portion of the PTH or stub to improve electrical performance. Design data identifies the unused segment of PCB PTH. The stub is precisely drilled out leaving the remaining PTH intact. However, this method has drawbacks such as an extra drilling process step, yield loss at a final stage of PCB manufacture, loss of wiring area around back-drilled PTH, and the additional cost these elements drive in the PCB. For these reasons, back-drilling is only applied when required for electrical performance to vias with unused portions that are longer than a predetermined maximum stub length.

Maximum allowable stub length can be determined based on a circuit simulation using a computer simulation program. PCB electrical circuit simulation uses the required frequency, data rate, design objectives for performance, and similar inputs to predict electrical circuit performance. For example, computer software programs such as HFSS by Ansys Corporation can be used to calculate PCB scattering parameters (S-parameters). S-parameters look at the effect of discontinuities on a current (or voltage) on a transmission line. Effects like insertion loss and return loss due to a via or other discontinuity on a high speed PCB circuit can be calculated. Depending on the frequency required, data rate, signal integrity and associated cost objectives, a maximum stub length for a specific application can be determined by a PCB designer based on the circuit simulation results.

However, as designs move to higher and higher speed applications, additional performance advantages are needed in applications where cost is very much an issue. Exemplary embodiments of this invention propose a method to reduce the effects of a signal discontinuity of a via on a high frequency PCB design without increasing the cost of the PCB.

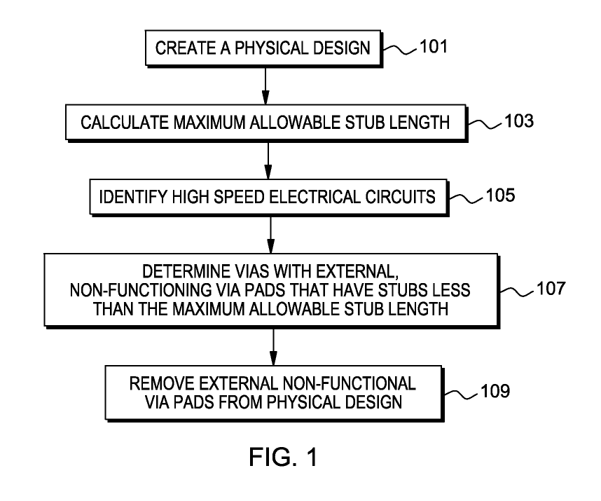

FIG. 1 is a flow chart illustrating exemplary steps of an embodiment of the present invention. As shown in step 101, a designer creates a physical design or PCB layout using netlists, required electrical performance and manufacturing guidelines. This may also be referred to as a physical design layout. Typically, specialized computer software programs like Allegro PCB Design by Cadence Design Systems, for example, can generate the physical design layout.

In step 103, which can be done at any point prior to step 105, the designer or other engineering specialist for electrical performance modeling develops the maximum allowable stub length using computer simulation software, electrical requirements for the application, and manufacturing specifications for the PCB.

In step 105, the designer identifies the electrical circuits or active transmission lines on the PCB that require high speed signal propagation. The evaluation of stubs occurs only on these identified high speed circuits. Inputted into the physical design program, the program can selectively evaluate only vias associated with these high speed electrical circuits.

Step 107 can identify vias with external non-functioning via pads that have stub lengths less than the maximum allowable stub length. This identification occurs through the physical design tool which can analyze only vias which reside in specified high speed electrical circuits.

In step 109, the physical design tool, programmed to identify and remove external non-functional vias with stub length less than maximum allowable stub length, can remove identified external non-functional via pads from the physical design data. This via pad removal may be noted in a special drill file for manufacturers to use in the creation of specific manufacturing data (Gerber data, for example).

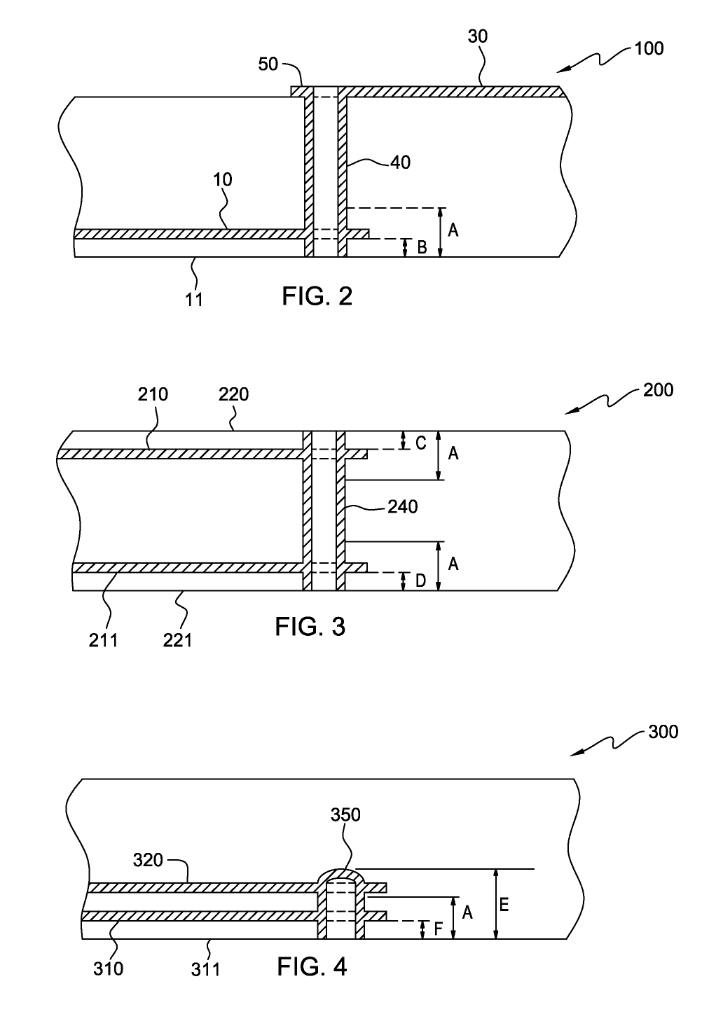

FIG. 2 depicts a cross-sectional view of a multilayered printed circuit board in accordance with an embodiment of the present invention. PCB 100 has a PTH 40, an external functional via pad 50, a signal line 30 on an external layer connecting to via pad 50 and thence to PTH 40 and signal line 10 on an internal plane connecting to PTH 40. A maximum stub length A for the high speed circuit design on PCB 100 is shown. For the purposes of the present invention, maximum stub length A is measured from the bottom surface of external layer 11 on PCB 100 to depth A in the internal layers PCB 100.

The portion of PTH 40 that is unused for electrical signal transmission is portion B. Portion B is measured from the bottom surface of external layer 11 to intersection of signal line 10 and PTH 40 as shown in FIG. 2. A signal line 10 connects to the PTH at a distance B less than the maximum allowable stub length A from the bottom surface of PCB. Since the unused portion B of PTH 40 is less than the maximum allowable stub length A, this portion of the PTH 40 can remain according to standard design practice. To minimize the effect of this discontinuity on a high speed circuit, an exemplary embodiment of the invention can remove the external non-functioning via pad on the bottom surface 11 of PCB 100. Removing the external non-functioning via pad reduces the capacitive coupling of PTH 40 to the surrounding ground and power planes (not shown). The removal of non-functioning external via pads also reduces the discontinuity caused by the complex impedance of the via structure. PTH 40, without a non-functional external via pad on external layer 11, improves performance of the high speed circuit and can provide a slight improvement in PCB yields due to increased spacing between circuit elements (no external via pad) and less yield loss due to external circuitization imperfections of via pad at inspection. These yield improvements can result in a lower cost PCB. In addition, removal of the external via pad may create enough space on the external layer of the PCB to allow additional circuit lines. Embodiments of this invention may allow for greater wiring density on the external PCB surface and/or a reduced PCB cost while providing better high speed performance. In a preferred embodiment, the identified external non-functioning via pad may be removed from the printed circuit board design and may not be present in the manufacturing data or glass used to create the PCB external circuitry. In an alternate embodiment, the identified external non-functioning via pad can be physically removed from a PCB structure.

FIG. 3 illustrates a cross-sectional view of a multilayered printed circuit board in accordance with an embodiment of the present invention. PCB 200 has PTH 240, circuit lines 210 and 211 that connect with PTH 240 at a distance C and D respectively less than the maximum allowable stub length A from the surface of external layers 220 and 221, respectively. External non-functional via pads normally used at the ends of PTH 240 can both be removed from the design resulting in the illustrated PTH structure for a high speed via shown in FIG. 2. This PCB design with external non-functioning via pads removed from PTH 240 provides the same advantages for a high speed via as described on FIG. 2. Removing the non-functional PTH pads from both sides of the PCB provides the advantage, as before, of a reduced capacitive coupling of the PTH to surrounding ground and power planes for high speed applications. Without the use of these non-functional via pads a similar reduction in signal discontinuity can be achieved in the high speed electrical design. This embodiment of the present invention also can provide twice the improvement in wiring area since additional wiring area is provided on both external layers 220 and 221 when external non-functional PTH pads are removed.

FIG. 4 depicts a cross-sectional view of a multilayered printed circuit board in accordance with an embodiment of the present invention. PCB 300 using a blind via 350 with a depth E and signal lines 310 and 320 are shown. Signal line 310 connects with blind via 350 at a depth F making the portion F of blind via 350 a stub since it is not used in the active signal transmission path. Since the stub created by portion F in blind via 350 is less than maximum allowable stub length A, the non-functional external via pad for blind via 350 can be removed from the design. The resulting PCB 300 with external non-functional via pads removed provides similar advantages in high speed circuit performance providing reduced capacitive coupling between surrounding power and ground planes and via 350 along with less signal discontinuity in the high speed circuit. As in previous embodiments, the removal of the blind via pad from via 350 can provide advantages in wiring area and/or PCB yield or cost.

Computer simulation programs for PCB circuit design and simulation, HFSS, for example, and physical design programs such as Allegro PCB Design, for example, can run on a computer, having at least one or more computer processors and one or more computer-readable storage devices, which may be a desktop computer, laptop computer, personal computer, netbook computer or any other programmable device capable of running a design program, e.g., HFSS simulation program and/or Allegro PCB Design, or a computer capable communicating with a computer processor over a network, for example, a local area network (LAN), a wide area network (WAN) such as the Internet or a combination of the two, and can include wired, wireless or fiber optic connections.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Having described preferred embodiments of a high speed via (which are intended to be illustrative and not limiting), it is noted that modifications and variations may be made by persons skilled in the art in light of the above teachings. It is therefore to be understood that changes may be made in the particular embodiments disclosed which are within the scope of the invention as outlined by the appended claims.

What is claimed is:

1. A method for designing a multilayered circuit substrate, the method comprising:
generating a physical design layout wherein the physical design layout is a representation of at least one electrical circuit passing through a plurality of layers;
based on performance requirements of the electrical circuit, determining, by one or more computer processors, a maximum allowable stub length of a via of the electrical circuit;
determining, by one or more computer processors, whether a stub length of an existing via in the physical design layout of the electrical circuit is less than the maximum allowable stub length; and
in response to determining that the stub length of the existing via is less than the maximum allowable stub length, removing an external non-functional pad of the existing via from the physical design layout.

2. The method of claim 1, further comprising:
determining that a stub length corresponding to an opposite end of the existing via is less than the maximum allowable stub length, and in response, removing a second external non-functioning pad, corresponding to the opposite end of the existing via, from the physical design layout.

3. The method of claim 1, wherein the multilayered circuit substrate is a printed circuit board.

4. The method of claim 1, further comprising:
prior to determining whether the stub length of the existing via is less than the maximum allowable stub length, identifying, by one or more computer processors, the electrical circuit as a high speed electrical circuit.

5. The method of claim 1, further comprising:
building the multilayered circuit substrate according to the physical design layout.

6. A multilayered circuit substrate comprising:
a plurality of electrical circuits passing through a plurality of layers of a multilayered circuit substrate, wherein each of the plurality of electrical circuits comprises at least one via electrically connecting a respective first and second conductive layer within the plurality of layers;
wherein each via, of the plurality of electrical circuits, having a stub-length less than a defined maximum allowable stub-length, terminates at an external layer of the plurality of layers without a non-functioning conductive pad; and
wherein each via, of the plurality of electrical circuits, having a stub-length equal to or greater than the defined maximum allowable stub-length, terminates at an internal layer wherein a stub of the via has been removed.

7. The multilayered circuit substrate of claim 6, wherein each of the plurality of electrical circuits are high speed electrical circuits.

8. The multilayered circuit substrate of claim 6, wherein at least one via having a stub-length less than the defined maximum allowable stub-length, is a plated-through-hole.

9. The multilayered circuit substrate of claim 8, wherein the at least one via, that is a plated-through-hole, terminates on an opposite external layer without a non-functioning conductive pad.

10. The multilayered circuit substrate of claim 6, wherein at least one via having a stub-length less than the defined maximum allowable stub-length, is a blind via.

11. The multilayered circuit substrate of claim 6, wherein the multilayered circuit substrate is a printed circuit board.
